(19) United States
(12) Patent Application Publication
(10) Pub. No.: US 2026/0051467 A1
(43) Pub. Date: Feb. 19, 2026

(54) MIXED GAS ATMOSPHERIC PRESSURE PLASMA

(71) Applicant: Surfx Technologies LLC, Redondo Beach, CA (US)

(72) Inventors: Sepehrdod Tom Saremi, Los Angeles, CA (US); Hsiao-Wen Liu, Taichung City (TW); Robert F. Hicks, Redondo Beach, CA (US)

(73) Assignee: Surfx Technologies LLC, Redondo Beach, CA (US)

(21) Appl. No.: 19/001,334

(22) Filed: Dec. 24, 2024

Related U.S. Application Data
(60) Provisional application No. 63/684,298, filed on Aug. 16, 2024.

(51) Int. Cl. H01J 37/32; H01L 23/00

(52) U.S. Cl. CPC H01J 37/32825; H01J 37/32853; H01L 24/81; H01L 2224/81013; H01L 2224/81022; H01L 2224/81092; H01L 2224/81203

(57) ABSTRACT

An atmospheric pressure plasma apparatus and method are disclosed that operate with a multigas mixture to provide a high concentration of reactive neutral species for cleaning and activating the surfaces of substrates, including those with metal interconnects embedded in the substrate.

### CROSS-REFERENCE TO RELATED APPLICATIONS

This application claims priority to: U.S. Provisional Patent Application No. 63/684,298, filed on Aug. 16, 2024, and titled ARGON HYDROGEN MIXED GAS ATMOSPHERIC PRESSURE PLASMA, (Attorney Docket No. SRFXP017.P1) the contents of which are hereby incorporated by reference in their entirety.

### FIELD OF THE INVENTION

The present disclosure is related to systems and methods for treating a substrate surface with a multigas plasma. In particular, the present disclosure is related to using multiple gases, for example, three gases, in a plasma to clean and activate a non-metallic substrate surface. In some embodiments, the non-metallic substrate is activated while the plasma also cleans and maintains a metallic portion of said substrate surface in the metallic state. For example, the substrate may consist of a semiconductor device with a dielectric film containing embedded copper pads for interconnects. The multigas plasma is used to clean and activate the dielectric film for fusion bonding and at the same time clean and remove any oxidation from the copper pads and to maintain them in the metallic state.

Various embodiments disclosed herein are further related to systems and methods for cleaning and activating surfaces with an atmospheric pressure plasma that uses multiple gases in such a way that no harmful reaction byproducts, such as ozone, are contained within the reactive gas beam generated by the plasma.

### BACKGROUND

Atmospheric pressure argon and oxygen (Ar+O₂) plasmas provide fast cleaning and activation of polymer and dielectric surfaces such as glass. For example, surface cleaning is a critical step in the stacking one semiconductor device on top of another. Two- and three-dimensional stacking of integrated circuits is at the forefront of semiconductor advanced packaging. These advanced packages are required across the spectrum of semiconductor devices, including memory, microprocessors and communication devices. Tremendous demand for these devices is being driven by applications in artificial intelligence, data storage in the cloud, high-performance computing, autonomous vehicles on land and in the air, and 5G communications.

In these examples, a key step in stacking chips is the bonding together of a two-dimensional array of interconnects. The pitch between interconnects is typically 30 microns or less in order to achieve required input/output (I/O) densities, and at the same time, provide communication speeds in the gigahertz range without significant signal loss. See, e.g., John H. Lau's book on Semiconductor Advanced Packaging (Springer, Singapore, 2021) as a guide to the many types of 2D and 3D packages that have been developed. Flip chip technology is the primary method of fabricating these advanced architectures. In this approach, a two-dimensional array of metal balls, bumps or pads is distributed across the back of the chips to be stacked together. A thermocompression bonder picks up the chip, flips it, aligns it with the second chip and bonds the metal interconnects together with the application of heat and/or pressure.

In thermocompression bonding (TCB), the interconnects can be made up of metallic micro-bumps, consisting of an array of copper pillars with tin/silver solder caps. In the packaging process, the oxide layer is removed from the solder caps, and the interconnects are joined by thermocompression. After the TCB step, the interconnects are protected by injection of underfill. Due to the extremely small pitch sizes, however, it is not practical to clean between the interconnects. Therefore, flux cannot be used because there is no way to remove the flux residue from between the soldered micro-bumps. As an alternative to flux, an atmospheric pressure hydrogen plasma may be employed to remove the oxide via the example reaction: CuO+2H=Cu+H₂O vapor. No organic residues are generated in this case. The TCB process can be configured for, for example, die-to-die or die-to-wafer bonding.

Hybrid bonding is an approach that takes advantage of the ability to fuse glass-like dielectric layers together by a hydrolysis reaction. The interconnects consist of an array of copper vias distributed throughout the dielectric layer. For example, a suitable dielectric such as silicon dioxide (SiO₂) is deposited onto the integrated circuit by plasma-enhanced chemical vapor deposition. Then an array of vias is etched through the dielectric and filled with copper metal. The substrates are carefully polished to produce an extremely smooth surface with dished-out copper pads. Any particles or debris left from the polishing step are washed away with a wet clean. Next, the dielectric is activated for bonding using a plasma process. It is critical that this process activate the dielectric without simultaneously oxidizing the metal pads. In fact, the plasma process may need to remove oxidation from the copper that may have occurred in previous processing steps. After plasma activation and a potential hydration step, the surfaces are joined together in a hybrid bonding machine. A post annealing step then causes the glass-like A and B surfaces to fuse together by the reaction: Si_{A}—OH—OH—Si_{B}═Si_{A}—O-Si_{B}+H₂O vapor. During annealing the copper vias expand and join together across the interface making a pure copper interconnect.

It is well known to those skilled in the art, that ionized gas plasmas are used to clean and activate dielectric surfaces for bonding. Such plasmas are weakly ionized, meaning that a very small fraction of the molecules in the gas is stripped of their electrons, generating free electrons and positively and negatively charged ions. The free electrons are accelerated to a high kinetic energy and subsequently smash apart molecules in the gas converting them into radicals such as, for example, O, N or H atoms. These reactive species are able to clean, activate, and etch material surfaces. The temperature in these weakly ionized gases is usually below 250 degrees Centigrade, so that thermally sensitive integrated circuits are not damaged by this processing step. A detailed discussion of plasmas used in semiconductor manufacturing is given by Lieberman and Lichtenberg, “Principles of Plasma Discharges and Materials Processing”, (John Wiley & Sons, Inc., New York, 2005).

According to the literature, weakly ionized plasmas are generated in a vacuum at pressures between 0.001 and 1.0 Torr. Electrical power is applied across two electrodes to break down the gas and ionize it. The electricity may be provided as a direct current (DC), alternating current (AC), radio frequency (RF), or microwave (MW) source. More recently, atmospheric pressure plasmas have been developed as an alternative to vacuum plasmas. These plasmas can treat an object of any size and shape, since they do not have to be loaded into a vacuum chamber. The design and operation of atmospheric pressure plasmas needs to be carefully considered if it is to be used for semiconductor manufacturing. In this case, the plasma must operate at low temperature, where the gas is weakly ionized, and the concentration of free electrons is exceptionally low.

Working with dielectric layers containing embedded metal interconnects, such as found in hybrid bonding, is complex and expensive. Achieving consistent bonding across the die-to-wafer interface is challenging, particularly with regard to surface quality requirements. In particular, the dielectric must be activated for fusion bonding, while at the same time, the metal is kept in a reduced, zero valent state. If an oxygen plasma is used to activate the dielectric it is highly likely that the copper pads will also be oxidized, creating a copper oxide (CuO) layer that prevents the formation of a highly conductive interconnect. Various embodiments described herein overcome these limitations inherent in the prior art.

A further drawback of oxygen plasmas, especially those at atmospheric pressure, is that they generate ozone. Ozone is harmful to human health, so much so that the recommended exposure limit is less than 0.1 parts per million over an eight-hour period. In order to avoid exposure to ozone, cabinets with exhaust abatement systems must be employed that add considerably to the cost of the equipment. The various embodiments disclosed herein also overcomes this limitation of the prior art.

### SUMMARY

Embodiments of the present invention include atmospheric pressure plasmas fed with a mixture of argon, nitrogen and hydrogen. These plasmas have been found to activate dielectric and polymer surfaces just as quickly and as effectively as atmospheric pressure plasmas fed with argon and oxygen. Instead of oxidizing metal components on the surfaces, however, the multigas plasma keeps the metal in a reduced metallic state. For example, when dielectric layers are fused together, a critical surface clean is essential prior to bonding. This surface clean can be performed by a weakly ionized vacuum plasma, or a weakly ionized atmospheric pressure plasma. In embodiments, organic contamination on the substrate surface is removed and the population of silanol groups (Si—OH) is increased to a maximum. Metallic interconnects embedded in the dielectric layer must be kept in a pristine state in order to provide a secure electrical connection. Activating, for example, a dielectric layer without incurring oxidation of the metallic interconnects would be helpful in maintaining the conductivity of the interconnects. Likewise, if the metallic interconnects already have a surface layer of oxidation, removing this oxidation with a plasma process prior to bonding would be beneficial.

In an embodiment, a method for treating a substrate with an atmospheric pressure plasma comprises directing, from an inlet into a housing in a plasma-creation device, a gas flow comprising a multigas mixture of at least three different species, for example, argon, hydrogen, and nitrogen. A power supply, such as a radio frequency (RF) power supply, is delivered to ionize the gas flow to produce a plasma having reactive neutral species derived from the at least three different species. In this process, no harmful ozone byproduct is generated. Once the plasma is created, it is moved relative to the substrate at a predetermined scanning speed, such that the reactive species flowing out of the plasma impinge on the substrate surface and clean and activate it. The substrate surface may be nonmetallic, such as for example, a dielectric, a metal oxide, a glass or glass-like material, a polymer, or a semiconductor. The substrate surface may contain a nonmetallic portion along with a metallic portion. In this embodiment, the nonmetallic portion, e.g., a dielectric, is cleaned and activated, while the metallic portion is cleaned and also maintained in the reduced metallic state. In another embodiment, the substrate consists of a dielectric layer with metallic interconnects embedded within the dielectric layer. The reactive species generated from the multigas plasma clean and activate the dielectric portion for subsequent fusion bonding, while at the same time, cleaning and maintaining the metallic interconnects in the metallic state. This treatment is accomplished without relying on a passivation layer to prevent the metallic interconnects from undergoing reoxidation.

In an embodiment, the multigas mixture comprises a combination of argon, nitrogen and hydrogen in predetermined percentages as inputs to a plasma device, and which are converted into the reaction products of the plasma used to clean and activate the substrate surface. The substrate in this case is a nonmetallic material, such as but not limited to, a dielectric, a metal oxide, a glass or glass-like material, a polymer, or a semiconductor. In another embodiment, the reaction products from the plasma fed with multiple gases is used to clean and activate the substrate surface, while simultaneously removing surface oxides from metallic interconnects embedded in the substrate surface and maintaining them in a metallic state without relying on a passivation layer. The substrate to be cleaned and activated with the plasma can include, depending on the embodiment, a dielectric, a polymer, a semiconductor, a metal, or any combination of these materials.

In an embodiment, an apparatus is provided for treating a substrate with an atmospheric pressure plasma, where the substrate consists of a dielectric, a polymer, a semiconductor, a metal, or any combination of these materials. In another embodiment, the substrate surface comprises a non-metallic layer along with a metallic layer. The apparatus includes a housing to support an inlet for flow of a multigas mixture of at least three different species combined in a predetermined ratio. The apparatus includes electrodes and a power supply to create a plasma comprising reactive neutral species that can clean and activate the substrate surface. The apparatus further includes a platform such that the atmospheric pressure plasma and the substrate can be moved relative to each other such that the plasma cleans and activates the substrate surface. Provided the substrate surface contains metallic interconnects embedded within in it, then the substrate is cleaned and activated while at the same time, the metallic interconnects are cleaned and maintained in a metallic state without relying on a passivation layer.

In one exemplary embodiment a method for activating a substrate with a plasma comprises directing, from an inlet to a housing configured to define a path for gas flow within the housing, a gas flow comprising a multigas mixture of at least three different gas species combined in a predetermined ratio, directing the gas flow within the housing between a powered electrode and a grounded electrode, delivering power from a power supply to ionize the gas flow and produce the plasma comprising reactive neutral species for activating the substrate, and moving the substrate and the plasma relative to each other at a predetermined scanning speed, such that the plasma activates the substrate. The at least three different gas species can be argon, nitrogen, and hydrogen. The substrate can comprise at least one of an insulator, a semiconductor, a polymer, or a metal. The predetermined scanning speed can be between 0.5 and 250 mm/s. The plasma can be created from a combination of argon, hydrogen, and nitrogen gas at a predetermined ratio, wherein the argon comprises 97.0% to 99.5% of the gas mixture, and the hydrogen to nitrogen ratio varies from 0.05 to 5.0. Typically, the plasma can be at atmospheric pressure.

In further embodiments of the method above, the substrate can be held at a temperature between room temperature and 200 degrees C. or alternately the substrate can be not heated (or thermally controlled). The substrate can further comprise a dielectric portion and a metallic portion, and wherein the reactive neutral species generated by the plasma prepares the dielectric portion for hybrid bonding, while maintaining the metallic portion in a clean, reduced metallic state. The method can further comprise moving the substrate to a hybrid bonder and hybrid bonding the substrate to at least one of a wafer or die.

Similarly, an exemplary apparatus embodiment for activating a substrate with a plasma comprises a housing configured to support an inlet for a gas flow that comprises a multigas mixture of at least three different gas species combined in a predetermined ratio, the housing configured to define a path for gas flow within the housing, a powered electrode and a grounded electrode, at least the powered electrode being disposed within the housing, the path for gas flow being disposed between the powered electrode and the grounded electrode, a power supply coupled to both the powered electrode and the grounded electrode, the power supply configured to deliver power sufficient to produce, from the multigas mixture, a plasma comprising reactive neutral species for activating the substrate, and a support for the substrate configured to move the substrate and plasma source relative to each other at a predetermined scanning speed, such that the plasma activates the substrate. This apparatus embodiment can be modified consistent with the foregoing method embodiment.

Another exemplary apparatus embodiment for treating a substrate with a plasma, the substrate including a layer having a non-metallic portion and a metallic portion comprises a housing configured to support an inlet for gas flow that comprises a multigas mixture of at least three different gas species combined in a predetermined ratio, the housing configured to define a path for gas flow within the housing, a powered electrode and a grounded electrode, at least the powered electrode being disposed within the housing, the path for gas flow being disposed between a powered electrode and a grounded electrode, a power supply for delivering electrical power coupled to both the powered electrode and the grounded electrode, the power supply configured to deliver power sufficient to produce, from the gas flow, a plasma comprising reactive neutral species for cleaning and activating the non-metallic portion while cleaning the metallic portion and maintaining the metallic interconnects in a metallic state, and a support for the substrate configured to move the substrate and plasma source relative to each other at a predetermined scanning speed, such that the plasma cleans and activates the non-metallic portion while cleaning the metallic portion and maintaining the metallic portion in a metallic state. The at least three different gas species can be argon, nitrogen, and hydrogen. The non-metallic portion can be at least one of an insulator, semiconductor, or a polymer. The plasma can be further configured to maintain the metallic portion in a metallic state without the need for a passivation layer. The predetermined scanning speed can be between 0.5 and 250 mm/s. The plasma can be created from a combination of argon, hydrogen, and nitrogen gas at a predetermined ratio, wherein the argon comprises 97.0% to 99.5% of the gas mixture, and the hydrogen to nitrogen ratio varies from 0.05 to 5.0. Typically, the plasma can be at atmospheric pressure.

In further embodiments of the apparatus above, the plasma can be at atmospheric pressure or alternately at vacuum pressure. The substrate can be held at a temperature between room temperature and 200 degrees C. or alternately the substrate can be not heated (or thermally controlled). The apparatus can further comprise a hybrid bonder configured to receive the prepared substrate and to hybrid bond the prepared substrate to at least one of a wafer or die. The metallic portion can comprise metal interconnects.

Similarly, an exemplary method for treating a substrate with a plasma, the substrate including a layer having a non-metallic portion and a metallic portion, comprises directing, from an inlet to a housing configured to define a path for gas flow within the housing, a gas flow comprising a multigas mixture of at least three different gas species combined in a predetermined ratio, directing the gas flow within the housing between a powered electrode and a grounded electrode, delivering power from a power supply to ionize the gas flow and produce the plasma comprising reactive neutral species for cleaning and activating the non-metallic portion while cleaning the metallic portion and maintaining the metallic portion in a metallic state, and moving the substrate and the plasma relative to each other at a predetermined scanning speed, such that the plasma cleans and activates the non-metallic portion while cleaning the metallic portion and maintaining the metallic portion in a metallic state. This method embodiment can be modified consistent with the foregoing apparatus embodiment.

### BRIEF DESCRIPTION OF THE DRAWINGS

Embodiments are illustrated by way of example, and not by way of limitation, in the figures of the accompanying drawings and in which like reference numerals refer to similar elements and in which:

FIGS. 1a and 1b are two views of a schematic representation of a system for producing a reactive gas plasma, according to an embodiment of the invention.

FIG. 1c is a schematic representation of a system for treating a substrate, according to an embodiment of the invention.

FIG. 2 is a flowchart of a method for treating a substrate, according to an embodiment of the invention.

FIG. 3 is a flowchart of a method for treating a substrate, according to an embodiment of the invention.

FIG. 4 shows two graphs of the change in water contact angle and surface free energy of the native oxide on silicon with exposure time to an argon and oxygen plasma and an argon, hydrogen and nitrogen plasma at atmospheric pressure and room temperature, according to an embodiment.

FIG. 5 shows two graphs of the change in water contact angle and surface free energy of the CFRC surface with exposure time to an argon and oxygen plasma and an argon, hydrogen and nitrogen plasma at atmospheric pressure and room temperature, according to an embodiment.

FIG. 6 displays copper oxide removal upon multiple scans with an atmospheric pressure plasma fed with argon, hydrogen and nitrogen at a substrate temperature of 150° C. in an inert gas chamber, wherein the ratio of H₂:N₂ fed to the plasma was 3.4 to 1.0, according to an embodiment.

FIG. 7 displays copper oxide removal by exposure to a stationary atmospheric pressure plasma fed with argon, hydrogen and nitrogen, wherein the substrate was not heated. The ratios of H₂ to N₂ fed to the plasma were 2 to 1 and 1 to 1, according to an embodiment.

FIG. 8 displays copper oxide removal by exposure to a stationary atmospheric pressure plasma fed with argon, hydrogen and nitrogen, wherein the substrate was not heated. The ratios of H₂ to N₂ fed to the plasma were 1 to 2 and 1 to 4, according to an embodiment.

FIG. 9 displays copper oxide removal by exposure to a stationary atmospheric pressure plasma fed with argon, hydrogen and nitrogen, wherein the substrate was not heated. The ratio of H₂ to N₂ fed to the plasma was 1 to 20, according to an embodiment.

FIG. 10 displays side and bottom views of the atmospheric pressure plasma operated with argon and nitrogen at 550 and 350 W, and operated with argon, nitrogen and hydrogen at 550 W and with ratios of hydrogen to nitrogen of 1 to 20 and 1 to 4, according to an embodiment.

### DETAILED DESCRIPTION

As described above, systems and methods for activating the surface of a substrate are disclosed using multiple gases, e.g., three gases, fed to an atmospheric pressure plasma. The substrate may consist of a single material, such as a dielectric metal oxide, a glass or glass-like material, a polymer, a semiconductor, or a metal. The substrate may also consist of a combination of materials, such that it contains a non-metal portion and a metal portion. The surface of the non-metal portion is cleaned and activated by the atmospheric pressure plasma, while the surface of the metal portion is cleaned and also maintained in a metallic state (also known as the reduced state) by the atmospheric pressure plasma. In embodiments, various systems and methods described herein can be used to prepare such substrates for, e.g., (a) bonding together interconnects for semiconductor packaging, (b) underfilling the interconnected space after bonding, or (c) encapsulating the interconnects after bonding.

More specifically, techniques described herein can be employed to activate the surface of a substrate while concurrently cleaning the metallic interconnects and maintaining the metallic interconnects in a metallic (also known as a reduced) state, thereby enhancing adhesion of the dielectric to another dielectric while ensuring proper electrical connection. In some embodiments, the techniques can be employed to activate the surfaces of dielectric materials, such as silicon dioxide, and/or polymers, such as carbon-fiber-reinforced composite (CFRC), thereby enhancing adhesion between the material and an adhesive. In some embodiments, the techniques can be employed to kill microorganisms on a surface, thereby sterilizing the substrate; or etching materials from a substrate. In each of these cases, the plasma process can be carried out while simultaneously removing oxidation from metallic portions of the substrate.

In certain embodiments, the plasma operates at atmospheric pressure, at low temperatures, and with high concentrations of reactive species in the effluent stream. In certain embodiments, the plasma can be created in a vacuum, i.e., at pressures below 1.0 atmosphere. The techniques can be employed to remove organic contamination from a substrate, thereby cleaning the substrate.

One embodiment of the invention comprises an atmospheric pressure plasma apparatus that is fed with at least argon, nitrogen and hydrogen to activate a dielectric layer that contains metallic interconnects, and to maintain the metallic interconnects in a metallic, i.e., reduced state while removing, as necessary, metal oxidation from the metallic interconnects. The metal can, for example, be selected from the group comprising nickel, palladium, platinum, copper, silver, gold, gallium, indium, tin, lead, bismuth, and alloys thereof. The plasma is generated in a housing through which the gas flows and contacts two electrodes. The electrodes are driven by radio frequency power sufficient to break down the gas and convert it to an ionized gas discharge. The combination of gases creates a combination of radicals generated within this device that flow out of the device and onto a substrate that is placed downstream. The substrate comprising a dielectric surface with metallic interconnects is contacted with the discharge, cleaning and activating the surface, while maintaining the metallic interconnects in a metallic, i.e., reduced state while removing, as necessary, metal oxidation from the metallic interconnects. To do this, the substrate is moved relative to the plasma beam at a predetermined speed. These speeds may vary between 1 and 250 mm/s.

The dielectric is activated by the reactive neutral species exiting the plasma, while the metal oxide on the surface of the metallic interconnects is removed by the reaction, MOₓ₍ₛ₎+2xH_{(g)}=M₍ₛ₎+xH₂O_{(g)} where the subscripts s and g refer to solid and gas, respectively. In the case of copper, for example, the reaction is CuO₍ₛ₎+2H_{(g)}═Cu₍ₛ₎+H₂O_{(g)}. In one embodiment of the invention, the substrate comprises one or more semiconductor devices, in the form of a die, wafer, board, panel, or other structure used in manufacturing and packaging integrated circuits.

In an example method shown herein, a low-temperature, atmospheric pressure plasma is produced by flowing a mixture of argon, nitrogen, and hydrogen through a housing containing two closely spaced electrodes, applying radio frequency power to one of the electrodes (while grounding the other) sufficient to strike and maintain the ionized gas plasma, and flowing reactive species out of the housing, while keeping the free electrons and ionized gas plasma inside the housing between the electrodes. When interacting with a substrate placed in the flow of the reactive neutral species, the substrate having, for example, a dielectric layer on one portion of the surface, and a metallic layer on another portion of the surface, the result is the activation of the dielectric layer while removing oxides from, and maintaining in a reduced state (without relying on a passivation layer), the metallic portion.

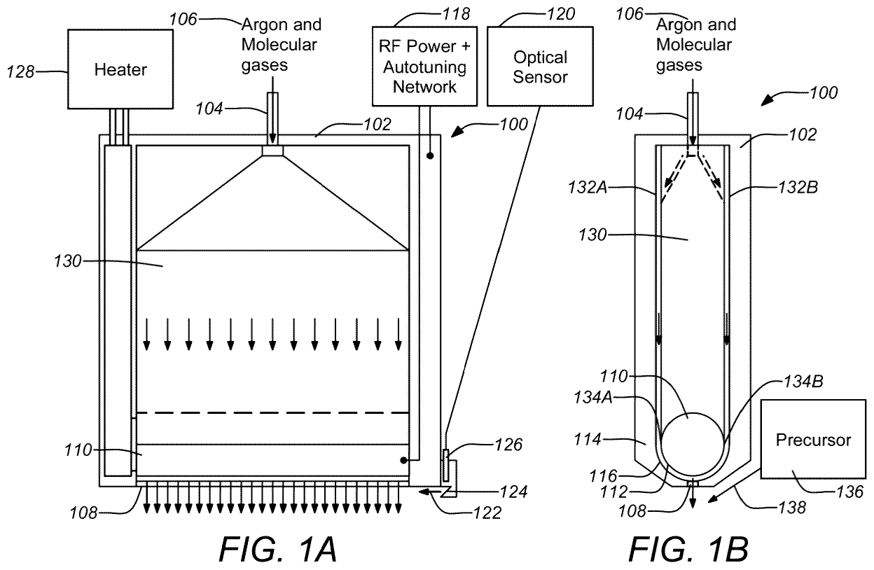

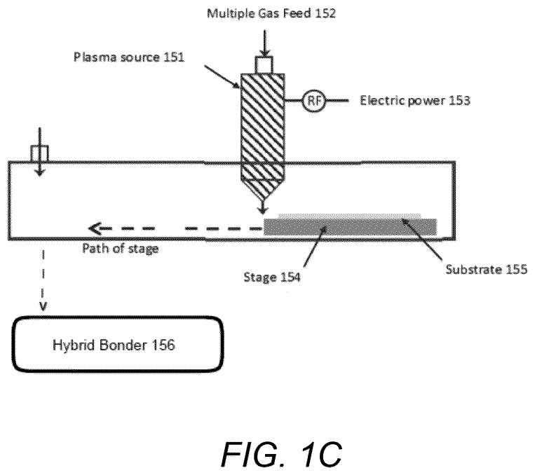

FIGS. 1A and 1B are schematic cross section diagrams of an exemplary plasma device 100 according to an embodiment of the invention for producing a low-temperature, atmospheric pressure plasma. The device 100 comprises a housing 102 which supports an inlet 104 for gas flow comprising a multigas mixture 106 of argon, nitrogen, and hydrogen, possibly along with one or more additional gases, and an outlet 108 from the device through which flows a gas containing argon along with a high concentration of reactive neutral species. In an embodiment, the molecular gases are added to the argon gas flow at a concentration between 0.1 to 5.0 volume %. The molecular gases, including for example, hydrogen and nitrogen, dissociate into atoms, e.g., H and N atoms, inside the plasma and then flow out of the device outlet onto the substrate. In this example, the outlet 108 comprises a linear opening.

FIG. 1C is a schematic of an embodiment of an apparatus including a plasma source 151 that is fed by gas flow 152. An electric power source 153 provides the power to create the plasma. A support such as a stage or platform 154 is disposed proximate to the opening of the plasma source 151 and holds a substrate 155, which is the intended target for the reactive neutral species. Stage 154 is configured to move relative to the plasma source 151 such that the reactive neutral species in the plasma traverse and treat the surface of the substrate 155. To move the substrate and beam relative to each other, in an embodiment, the support is connected to a robot assembly that puts the sample at a fixed distance from the plasma source and moves the sample at fixed speeds ranging from 1 to 250 mm/s relative to the plasma. This allows the sample to be translated underneath the plasma so that it can be uniformly treated over its entire surface. In an embodiment, the plasma head is swept across the surface of the substrate at one of the fixed speeds while the substrate is kept stationary. Once the substrate is treated by the plasma, it is ready for further treatment. In an embodiment, a hybrid bonder 156 is used to bond the substrate to a wafer or die.

Returning to FIG. 1A, a flow path within the housing 102 directs the gas from the inlet 104 toward a powered electrode 110. The powered electrode 110 disposed within the housing has a power electrode surface 112 that is exposed to the gas flow. A grounded electrode 114 is disposed adjacent to the powered electrode 110 such that a grounded electrode surface 116 is closely spaced from the power electrode surface 112 and the gas flow is directed therebetween. In this example, the entire housing 102 is the grounded electrode 114. However, those skilled in the art will understand that the grounded electrode 114 can be implemented as a separate component in the region near the grounded electrode surface 116. It is only necessary that the powered and grounded electrodes 110 and 114 are electrically isolated from one another, as will be readily understood by those skilled in the art.

A power supply 118 delivers radio frequency power to the powered and grounded electrodes sufficient to ionize the gas flow and produce the plasma comprising the reactive neutral species as the gas passes between the electrode surfaces 112 and 116. In addition, a heater/cooler 128 is coupled to the device 100 for heating/cooling one or both of the powered electrode 110 and the grounded electrode 114 as the gas flow is directed between the surfaces 112 and 116. The heater/cooler 128 heats or cools the electrodes as the case may be to a temperature between 4° and 100° C., but preferable between 4° and 80° C. Heating/cooling can be implemented through any suitable means. In the example device 100, however, the heater/cooler 128 comprises liquid, such as distilled water, at a temperature between 4° and 80° C. circulated through a hollow space within the powered electrode 110.

In an embodiment, the powered electrode can be coated with a non-metallic, non-conducting material between 1 and 100 microns thick. The dielectric coating on the powered electrode can be a hard, high temperature, non-porous coating such as glass (SiO₂), alumina (Al₂O₃), aluminum nitride (Al₃N₄), or similar inorganic electrical insulator. Note that reference to the “powered electrode surface” is still applicable if such a coating exists on the powered electrode, since direct physical contact between the conducting electrodes and the gas flow is not required as will be understood by those skilled in the art.

This example device 100 also employs an optical sensor 120 for receiving optical spectroscopy information of the plasma comprising the reactive neutral species at the outlet 108. In this example the optical spectroscopy information is from a line of sight 122 along the linear opening of the outlet 108 allowing for measurement of electronically excited species within the plasma. In addition, the device 100 employs a mirror 124 at one end of the linear opening for reflecting the optical spectroscopy information into the fiber optic feed 126 to the sensor 120.

In the example device 100, the flow path is formed by a laminar flow insert 130 disposed within a chamber within the housing 102. The laminar flow insert 130 directs the gas flow from the inlet 104 to two opposing walls 132A, 132B of the chamber (while spreading each half of the gas flow to be the width of the outlet 108) and then to two opposite sides 134A, 134B of the power electrode surface 112. The flow insert can be manufactured of a high temperature, insulating material that is resistant to plasma etching including thermoplastics, such as polyetheretherketone, perfluoroelastomers, such as Kalrez or Viton, fluoropolymers, such as Teflon, or ceramics such as alumina. The power electrode surface 112 comprises part of a cylindrical surface and the laminar gas flow is directed circumferentially along the part of the cylindrical surface toward the outlet 108. In this case the bifurcated gas flow converges at the outlet 108 as a reactive gas mixture after being weakly ionized between the electrode surfaces 112 and 116. Other geometries for the bifurcated gas flow could be used without deviating from the embodiments of this invention.

The example device 100 may be further modified or used in process according to the detailed examples in the following sections as will be understood by those skilled in the art. For example, the plasma creation device may use a system where the device housing acts as a grounded electrode. In another example, the plasma creation device can have a single inlet for gas and include a gas passage with a dielectric liner followed by a contained plasma zone to pass the gas between the grounded electrode and an RF electrode operating at ˜13.56 MHz at ˜80 Watts, where the plasma passes through an opening at the end of the contained plasma zone distal to the gas passage. Examples of applications for the devices and methods described herein include, without limitation, cleaning a material surface, activating a material surface for wetting, activating a material surface for adhesion, sterilizing a material, and etching a metal oxide layer, such as copper oxide, off of metallic interconnects within a substrate, and maintaining the interconnects in a metallic state. Furthermore, the outlets can be chosen from any appropriate shape known in the art, such as nozzle-type plasma heads, slit-shaped plasma heads, disc-shaped plasma heads, ring-shaped plasma heads, brush-type plasma heads, linear plasma heads, or any combination of plasma heads.

Notable embodiments can employ atmospheric pressure plasma devices described using a novel multigas mixture of argon, nitrogen and hydrogen in various applications. For example, such novel gas mixtures can yield atmospheric plasma that can activate the surface of glass (silicon dioxide), and if desirable, activate the surface of glass without oxidizing embedded copper contacts that can be applied in electronics manufacture. Those skilled in the art will appreciate that such embodiments, described in detail hereafter, can be implemented using the devices and methods described in U.S. Pat. No. 11,518,082, issued Dec. 6, 2022, and incorporated by reference herein in its entirety.

In an embodiment, the device fed with the multigas mixture described above can be used to prepare substrates for bonding, where it is beneficial to increase the surface free energy and/or wettability of the substrate's dielectric surface. In an embodiment, a plasma is struck using a mixture of argon, hydrogen and nitrogen, and the reactive gas produced therefrom is used to enhance the surface free energy of the substrate, making it more hydrophilic and so more amenable to bonding. Being more hydrophilic, the dielectric surface is more amenable to accepting adhesives, paints, inks and coatings that will come into intimate contact with the surface and adhere to it. In addition, the surface is more amenable to being joined to another dielectric surface by, in an embodiment, hybrid bonding. These substrates will adhere much more strongly and robustly than an untreated hydrophobic surface, allowing for greater reliability of bonded or coated parts.

### Example 1. Preparing a Semiconductor Substrate for Bonding

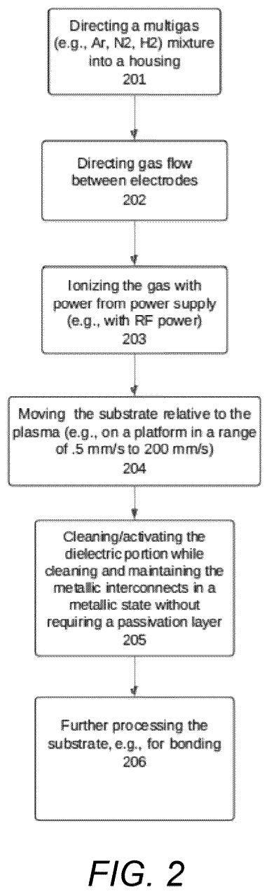

FIG. 2 is a flowchart of a method for using a plasma beam to prepare a semiconductor substrate, such as a silicon wafer, die or package for bonding. In an embodiment, the surface comprises a dielectric portion and a metallic portion. The substrate may, in an embodiment, be prepared for different types of bonding including hybrid bonding or thermocompression bonding. In an embodiment, the substrate includes a dielectric portion, such as silicon dioxide, that is activated for adhesion using the plasma beam. In yet another embodiment, the substrate includes other types of silicon-based dielectrics containing for example desirable mixtures of Si, O, C, N or H atoms. These other dielectrics are similarly activated for adhesion using the plasma beam.

As shown in FIG. 2, a multigas mixture of at least three gases is directed to the inlet of the housing for a plasma creation device. The multigas mixture, in an embodiment, includes a combination of argon (Ar), nitrogen (N₂) and hydrogen (H₂) that are all introduced through one or more inlets to the housing. One skilled in the art will understand that, for the purposes of safety, the H₂ molecules can be introduced through the use of, for example, a forming gas mixture containing 3.0 to 5.0% H₂ in Ar.

At 202, the gas flow mixture inside the housing is directed between powered and grounded electrodes so that, at 203, electrical power can be delivered by a power supply sufficient to ionize the multigas mixture, thereby creating a plasma made up of reactive neutral species. In an embodiment, the electrical power supplied is RF power. The plasma is created from the multigas mixture that includes at least three gases, such that the plasma is configured to activate and clean a substrate surface, wherein the substrate may be a polymer, a ceramic, an insulator, a semiconductor, or a metal, and any combination thereof.

For processing thermally sensitive materials, such as integrated circuits, it is desirable that the plasma be weakly ionized, so that it is uniformly distributed as a “glow discharge” between the electrodes, and so that the gas temperature stays low, preferably below about 300° C. In an embodiment, a weakly ionized plasma is struck in a vacuum and the cleaning process is performed in the vacuum. In an embodiment a weakly ionized plasma is struck at atmospheric pressure, and the cleaning process is performed at atmospheric pressure.

At 204, the plasma beam and substrate surface are moved relative to each other at a fixed speed to uniformly clean and activate the entire surface of the substrate. The substrate can be any material, or a combination of materials. In one embodiment, the substrate contains a dielectric portion, such as silicon dioxide, and a metallic portion, such as copper. The reactive gas species, such as N and H atoms, flowing out of the housing contact the substrate and remove organic contamination from the dielectric portion and the metallic portion. At the same time, the silicon dioxide is activated for bonding by the generation of a high concentration of silanol (Si—OH) groups on the surface. In addition, the reducing species in the plasma gas, e.g., the H atoms, remove any copper oxide that may be present on the copper surface. Passivation of the copper surface is neither necessary nor desired.

One skilled in the art will understand that moving the plasma beam across a substrate means moving the plasma beam and the substrate surface relative to one another such that, from the point of view of the substrate, the plasma beam is moved across the substrate surface. Thus, in an embodiment, the plasma beam is fixed while the substrate is moved, while in another embodiment, the substrate is fixed, and the plasma beam is moved. Alternatively, both the beam and the substrate may be moved relative to a fixed frame of reference. Furthermore, one skilled in the art will understand that the term substrate is used interchangeably with wafer or die, and is a workpiece having electronic components that may include surfaces having a non-metallic portion (e.g., a dielectric portion such as silicon dioxide), a polymer portion, or a metallic portion (e.g., copper interconnects in the form of vias or pads), or any combination of these three materials.

In FIG. 2 at 205, the substrate containing a non-metallic portion and a metallic portion is cleaned and activated by the plasma, while the metallic portion, for example metal interconnects, are also maintained in the metallic, i.e., reduced state. In the sections that follow, examples are given of the mixed-gas plasma process for cleaning and activating the native oxide on silicon, for cleaning and activating the epoxy resin of a carbon-fiber-reinforced composite, and for removing copper oxide from a copper substrate.

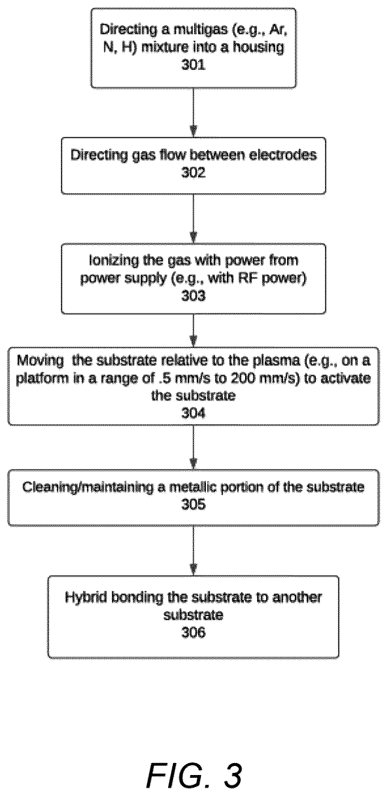

FIG. 3 shows a flowchart of a method for activating a substrate, according to an embodiment. The substrate comprises at least one of a dielectric material (e.g., glass), silicon, or a carbon fiber polymer. At 301, a multigas mixture is directed into the housing of a plasma device. In an embodiment, the multigas mixture comprises a mixture of argon, nitrogen, and hydrogen. At 302, the mixture is directed between electrodes, where RF power is supplied to ionize the gas at 303, creating a plasma. In an embodiment, the plasma is a low temperature plasma with the reactive gas at the outlet between 25 and 200° C. At 304, the substrate is activated by moving it relative to the plasma with a relative speed that can fall in the range of 0.5 mm/s to 250 mm/s, inclusive. In an embodiment, the relative speed is in the range of 0.5 mm/s to 10.0 mm/s, inclusive. The substrate may or may not be heated to temperatures up to 250° C. For example, for activating the surface of a dielectric, no heating is necessary, whereas for removing metal oxidation from metallic interconnects, a temperature above 150 degrees C. is necessary to achieve suitable process throughput.

One skilled in the art will appreciate that moving the substrate relative to the plasma head can include fixing the substrate, while the plasma head moves a plasma beam across the substrate; such relative motion can also include fixing the plasma head, while the substrate sits on a movable platform that moves through the plasma beam.

At 305, in an embodiment, the substrates includes a metallic portion, such as an electrical interconnect, and moving the substrate relative to the plasma includes the plasma cleaning the metallic portion while maintaining it in a metallic state.

At 306, once the substrate is cleaned and activated, it can be bonded to another substrate. In an embodiment, such bonding can be moved to a hybrid bonder, and then bonded to another substrate, wafer, or die, by hybrid bonding.

### Example 2. Cleaning and Activating the Native Oxide on Silicon

Shown in Table 1 is an example of cleaning and activating the native oxide on silicon with an atmospheric pressure argon and oxygen plasma using a device analogous to that described in FIG. 1. A plasma source with a 100 mm wide plasma beam was operated at 580 W of RF power at 27.12 MHz. The gas fed to the plasma source was 32.0 liters per minute (LPM) of argon and 0.19 LPM of oxygen. The amount of Ar in this gas mixture is 99.4%. Typically the amount of Ar fed to the atmospheric pressure plasma is between 97.0% and 99.5%, inclusive. In runs number 1 through 8, the plasma source was scanned over the substrate at speeds ranging from 250 mm per second (mm/s) down to 5 mm/s. The distance between the outlet of the plasma source and the substrate was 2 millimeters. After the native oxide on silicon was scanned with the oxygen and argon plasma beam, the water contact angle (WCA), surface free energy (SFE), dispersive component of the SFE, and polar component of the SFE was measured with a Kruss mobile surface analyst. The mobile surface analyst extracts the surface free energy from measurements of the surface contact angles of water and diiodomethane.

TABLE 1
Cleaning and activating the native oxide
on silicon with argon and O₂ plasma.

| | Run | Speed | WCA | SFE | Dispersive | Polar |
|---|---|---|---|---|---|---|
| Test | No. | (mm/s) | (°) | (mN/m) | (mN/m) | (mN/m) |
| Control | — | 0 | 32 | 67 | 37 | 30 |
| | — | 0 | 37 | 63 | 36 | 28 |
| Ar/O₂ | 1 | 250 | 14 | 75 | 41 | 35 |
| plasma | 2 | 150 | 14 | 75 | 40 | 35 |
| | 3 | 100 | 12 | 76 | 41 | 35 |
| | 4 | 75 | 9 | 76 | 39 | 37 |
| | 5 | 50 | 6 | 77 | 42 | 35 |
| | 6 | 25 | 6 | 77 | 41 | 36 |
| | 7 | 10 | 5 | 77 | 42 | 35 |
| | 8 | 5 | 6 | 76 | 38 | 38 |

As can be seen in Table 1, the WCA and SFE of the untreated control surface is on average 35° and 65 mN/m, respectively. After a scan of the plasma over the surface at 250 mm/s, the WCA falls to 14° and the SFE rises to 75 mN/m. At slower scan speeds between 5 and 50 mm/s, the WCA falls to a minimum of 6° and the SFE rises to a maximum of 77 mN/m. The dispersive and polar components of the surface free energy are on average 41 and 36 mN/m, respectively, after treatment. These results demonstrate that the native oxide on silicon is fully cleaned and activated with the atmospheric pressure, argon and oxygen plasma at scan speeds of up to 50 mm/s. Even at scan speeds of 250 mm/s the surface is close to being fully cleaned and activated.

A drawback of the atmospheric pressure, argon and oxygen plasma is that it produces ozone as a byproduct. Ozone is harmful to humans, and according to OSHA workers should not be exposed to more than 0.1 ppm of ozone over an eight-hour period. The plasma treatment process can be carried out in a vented enclosure that prevents personnel from being exposed to the ozone. Nevertheless, it would be advantageous to have a plasma process for cleaning and activating surfaces that is as fast as the argon and oxygen plasma but does not produce ozone. An embodiment of the invention that meets these requirements is an atmospheric pressure, argon, nitrogen and hydrogen plasma. Shown in Table 2 below is the amount of ozone generated by the atmospheric pressure plasma when using oxygen or when using a mixture of nitrogen and hydrogen. The oxygen plasma operated at 550 W, 32.0 LPM argon and 0.19 LPM oxygen generates more than 100 parts per million (ppm) of ozone at the source outlet. By contrast, the nitrogen and hydrogen plasma operated at 580 W, 36.6 to 39.7 LPM argon, and hydrogen to nitrogen ratios of 0.25 to 0.05 generates no detectable ozone.

TABLE 2
Comparison of ozone generated by the plasma
using O₂ or a mixture of N₂ and H₂.

| | Argon | O2 | N2 | H2 | | |
|---|---|---|---|---|---|---|
| Power | Flow | Flow | Flow | Flow | H2:N2 | Ozone |
| (W) | (LPM) | (LPM) | (LPM) | (LPM) | Ratio | (PPM) |
| 550 | 32.0 | 0.17 | 0.00 | 0.00 | — | 100+ |
| 580 | 36.6 | 0.00 | 0.29 | 0.07 | 0.25 | 0.0 |
| 580 | 39.7 | 0.00 | 0.29 | 0.01 | 0.05 | 0.0 |

The native oxide on silicon was cleaned and activated with the atmospheric pressure, argon, nitrogen and hydrogen plasma using the same device that was employed for the argon and oxygen plasma treatments above. In this case, a plasma source with a 100 mm wide beam was operated at 580 W of RF power at 27.12 MHz, and fed with 36.6 LPM of argon, 0.29 LPM of nitrogen and 1.4 LPM of 5% hydrogen in argon, yielding a H₂ to N₂ ratio of 0.25. The amount of Ar in this gas mixture was 99.06%. Typically, the amount of Ar in this plasma varies between 97.0% and 00.5%. The distance between the plasma source and the substrate surface was 2.0 mm. Table 3 shows the effect of different plasma scan speeds on the water contact angle and surface free energy of the silicon dioxide surface. At a scan speed of 250 mm/s, the WCA drops from 35° for the untreated control down to 16°, and the surface free energy increases from 65 to 75 mN/m. At scan speeds of 5 to 50 mm/s, the atmospheric pressure, argon, nitrogen and hydrogen plasma fully cleans and activates the native oxide on silicon, producing an average WCA of 11° and an SFE of 76 mN/m. Within the experimental error of the measurements, these results demonstrate that the argon, nitrogen and hydrogen plasma activates the native oxide on silicon just as fast as the argon and oxygen plasma.

TABLE 3
Cleaning and activating the native oxide
on silicon with argon, N₂ and H₂ plasma.

| | Run | Speed | WCA | SFE | Dispersive | Polar |
|---|---|---|---|---|---|---|
| Test | No. | (mm/s) | (°) | (mN/m) | (mN/m) | (mN/m) |
| Control | — | 0 | 32 | 67 | 37 | 30 |
| | — | 0 | 37 | 63 | 36 | 28 |
| Ar/H₂/N₂ | 9 | 250 | 16 | 75 | 42 | 33 |
| plasma | 10 | 150 | 12 | 75 | 38 | 37 |
| H₂:N₂ = | 11 | 100 | 13 | 75 | 41 | 34 |
| 0.25 | 12 | 75 | 11 | 76 | 42 | 35 |
| | 13 | 50 | 12 | 76 | 42 | 34 |
| | 14 | 25 | 11 | 76 | 42 | 35 |
| | 15 | 10 | 11 | 76 | 42 | 35 |
| | 16 | 5 | 9 | 77 | 43 | 34 |

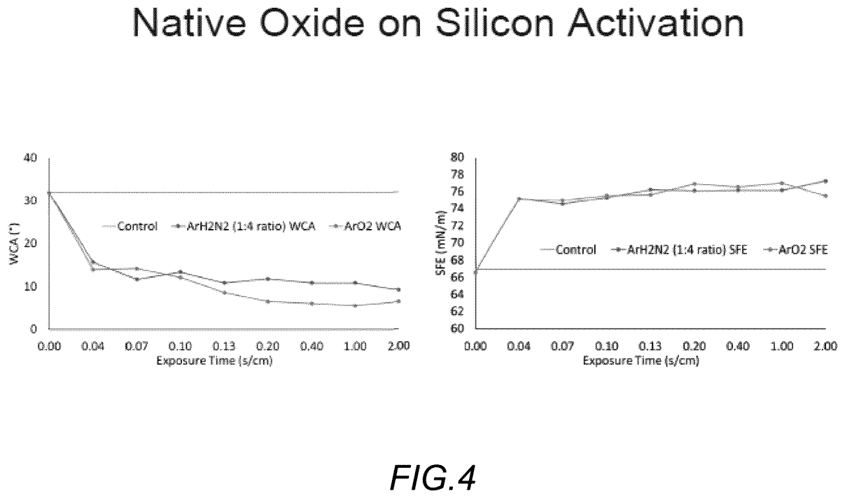

In FIG. 4, a comparison is provided of the cleaning and activation of the native oxide on silicon with the atmospheric pressure, argon and oxygen plasma versus the atmospheric pressure, argon, nitrogen and hydrogen plasma. The plot on the left shows the dependence of the water contact angle (WCA) on the exposure time to the plasma, while the plot on the right shows the dependence of the surface free energy (SFE) on the exposure time to the plasma. The exposure time (in units of seconds per centimeter (s/cm)) equals the inverse of the scan speed. Inspection of the trends in the figures reveals that the N₂/H₂ plasma is just as effective at cleaning and activating the SiO₂ surface as the O₂ plasma, since the data points essentially overlay on top of each other.

It is obvious to one skilled in the art that the mixed gas plasma, fed with argon, nitrogen and hydrogen, could be used to clean and activate the surface of other dielectric materials, such as silicon nitride, silicon carbide, silicon oxynitride and silicon carbonitride. Similarly, the mixed gas plasma could be used to clean and activate the surface of metal oxides, such as, but not limited to aluminum oxide, titanium dioxide, zirconium dioxide, hafnium dioxide, nickel oxide, iron oxide and many different combinations of transition metal oxides. Furthermore, the ratio of nitrogen to hydrogen employed in the mixed gas plasma can be varied over a wide range without deviating from the scope of the invention.

### Example 3. Cleaning and Activating Epoxy Composite Surfaces

This example demonstrates how the invention may be employed to clean and activate polymer surfaces. The surface chosen to treat with the atmospheric pressure plasma was a carbon-fiber-reinforced epoxy composite (CFRC). The surface is comprised of epoxy polymer resin. Presented in Table 4 is the dependence of the water contact angle and surface free energy of the polymer surface on the scan speed. In this experiment, the atmospheric pressure plasma source with 100 mm wide beam was operated at 550 W RF power, 32.0 LPM argon, 0.17 LPM oxygen, and an offset of 3 mm. Faster scan speeds correspond to shorter exposure times to the plasma. It is seen that the water contact angle drops from 75 to 25 degrees at a scan speed of 200 mm/s, and it bottoms out at 10 degrees at scan speeds of 10 mm/s or less. In similar fashion, the surface free energy increases from 53 mN/m for the untreated control to 74 mN/m at a scan speed of 200 mm/s, and maxes out at 80 mN/m at a scan speed of 10 mm/s. Of particular note is the change in the polar component of the surface free energy, because it is an indicator of the surface's receptiveness to forming chemical bonds with adhesives. It is only 3 mN/m for the untreated surface, and maxes out at 32 mN/m when the surface is fully activated.

TABLE 4
Cleaning and activating epoxy composite
with argon and O₂ plasma.

| | Run | Scan speed | WCA | SFE | Dispersive | Polar |
|---|---|---|---|---|---|---|
| Test | No. | (mm/s) | (°) | (mN/m) | (mN/m) | (mN/m) |
| Control | — | 0 | 75 | 53 | 50 | 3 |
| Ar/O₂ | 1 | 200 | 25 | 74 | 46 | 28 |
| plasma | 2 | 100 | 22 | 74 | 43 | 31 |
| | 3 | 50 | 20 | 75 | 45 | 30 |
| | 4 | 25 | 18 | 77 | 47 | 30 |
| | 5 | 10 | 10 | 80 | 48 | 32 |
| | 6 | 5 | 10 | 80 | 48 | 32 |

It is instructive to see how well the mixed gas plasma cleans and activates the carbon-fiber-reinforced composite. This plasma process has the important advantage of not generating ozone. Shown in Table 5 is the effect of the scan speed of the mixed gas plasma on the water contact angle, the surface free energy, the dispersive component of the SFE, and the polar component of the SFE. The atmospheric pressure plasma source with 100 mm wide beam was operated at 580 W RF power, 39.7 LPM argon, 0.28 LPM nitrogen, 0.29 LPM of 5.0% hydrogen in nitrogen, and an offset of 3 mm. The ratio of hydrogen to nitrogen fed to the plasma was 0.05. Inspection of the table reveals that exposure to the mixed gas plasma at 200 mm/s scan speed causes the WCA to decrease from 75 to 52 degrees, the SFE to increase from 53 to 58 mN/m, and the polar component of the SFE to increase from 3 to 17 mN/m. While the effect of the mixed gas plasma on the surface at high scan speeds is not as dramatic as with the oxygen plasma, the former recipe is still able to achieve complete activation at a scan speed of 10 mm/s. At this scan speed the WCA, SFE and polar component of the SFE on the composite surface is 13°, 78 mN/m and 32 mN/m, respectively, after treatment.

TABLE 5
Cleaning and activating the epoxy composite
with argon, N₂ and H₂ plasma.

| | Run | Scan speed | WCA | SFE | Dispersive | Polar |
|---|---|---|---|---|---|---|
| Test | No. | (mm/s) | (°) | (mN/m) | (mN/m) | (mN/m) |
| Control | — | Control | 75 | 53 | 50 | 3 |
| Ar/H₂/N₂ | 7 | 200 | 52 | 58 | 41 | 17 |
| plasma | 8 | 100 | 47 | 62 | 44 | 18 |
| H₂:N₂ = | 9 | 50 | 31 | 71 | 45 | 26 |
| 0.05 | 10 | 25 | 19 | 76 | 46 | 30 |
| | 11 | 10 | 13 | 78 | 46 | 32 |
| | 12 | 5 | 10 | 80 | 48 | 32 |

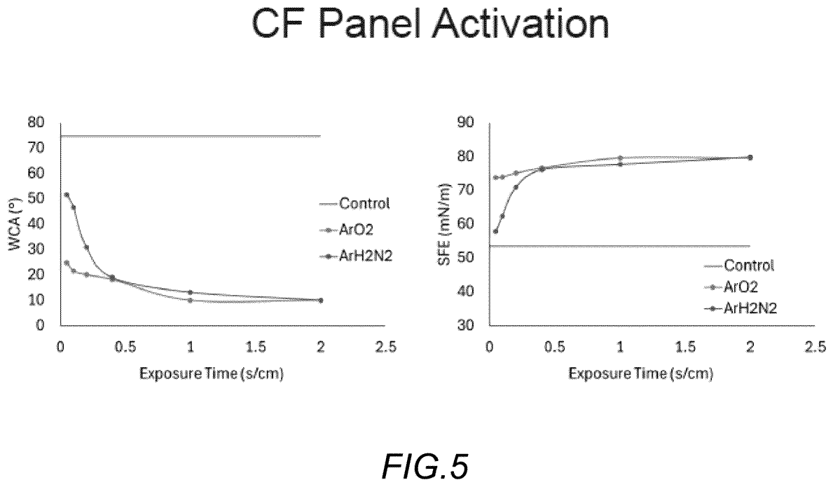

Shown in FIG. 5 are two plots of water contact angle and surface free energy as a function of exposure time of the carbon-fiber-reinforced composite to the atmospheric pressure, oxygen plasma and the atmospheric pressure, nitrogen and hydrogen plasma. At short exposure times, the oxygen plasma is clearly more effective than the mixed gas plasma at activating the polymer surface. Nevertheless, at exposure times beyond 0.4 s/cm (i.e., scan speeds of 25 mm/s or less), the results are the same for either recipe. In summary, the atmospheric pressure, argon, nitrogen and hydrogen plasma is a suitable alternative to the atmospheric pressure, argon and oxygen plasma for cleaning and activating the CFRC epoxy composite surface. Moreover, the multigas, Ar/N₂/H₂ plasma does not produce any ozone.

It is obvious to one skilled in the art that the mixed gas plasma, fed with argon, nitrogen and hydrogen, could be used to clean and activate the surface of other polymers, including, but not limited to polyethylene (PE), polypropylene (PP), polyimide (PI), polyethylene terephalate (PET), polyethylene glycol (PEG), polymethyl methacrylate (PMMA), polycarbonate (PC), and polyetheretherketone (PEEK). The embodiment will apply whether it is the polymer alone, or the polymer combined with glass or carbon fibers to make a composite. Furthermore, the ratio of nitrogen to hydrogen employed in the mixed gas plasma can be varied over a wide range without deviating from the scope of the invention.

### Example 4. Removing Copper Oxidation from Copper Substrates

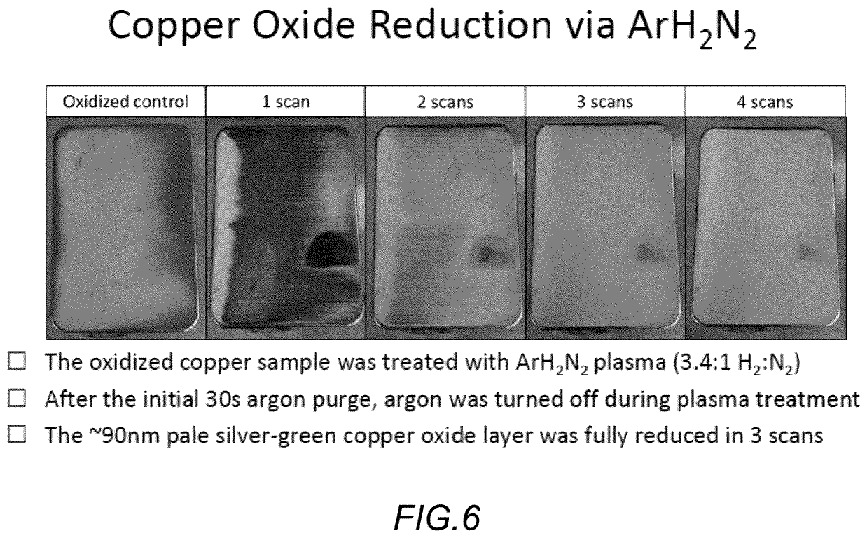

The foregoing examples illustrate that the mixed gas plasma is well suited for cleaning and activating dielectric and polymer surfaces for adhesion. One embodiment of the invention that is especially advantageous is that the mixed gas plasma will activate the dielectric and polymer surfaces while simultaneously keeping any exposed metal structures on the surface in a reduced metallic state. This is especially valuable for hybrid bonding where copper vias are embedded in the dielectric film, and the copper cannot have any copper oxide present when joining the vias on the dies and wafers together. In this example, the argon, hydrogen and nitrogen plasma is used to remove copper oxide films from copper coupons. Shown in FIG. 6 are a series of pictures of the copper oxide layer being removed from a copper coupon by exposing it to the mixed gas plasma. The initial color of the oxidized copper is yellow, indicating that the CuO layer was approximately 98 nanometers thick (see J. Lee, T. S. Williams, and R. F. Hicks, “Atmospheric pressure plasma reduction of copper oxide to copper metal,” J. Vac. Sci. Technol. A, vol. 39, 023001 (2021)). The atmospheric pressure plasma source with 100 mm wide beam was operated at 580 W RF power, 30.9 LPM argon, 0.08 LPM nitrogen, and 5.5 LPM of 5.0% hydrogen in argon. The H2:N2 ratio in this case was 3.4 to 1.0. The coupon was placed in an argon purge box on a heater that held the sample at 150° C. The plasma source was scanned over the coupon multiple times at a scan speed of 5 mm/s and an offset distance of 2 mm. Examination of FIG. 6 reveals that about half the copper oxide layer is removed in one scan, yielding a dark purple color corresponding to a CuO thickness of about 48 nm. After 2 scans, the oxide layer is nearly all gone, yielding the characteristic copper color. The oxide is completely gone after 3 and 4 scans. These results demonstrate that the mixed gas plasma, fed argon, nitrogen and hydrogen, removes oxidation from the copper surface. It is obvious to one skilled in the art that this same process would not cause any oxidation of the copper while dielectric and polymer surfaces are simultaneously activated. It is further obvious to one skilled in the art that the removal of the copper oxide layer on the copper occurs without the formation of a passivation layer.

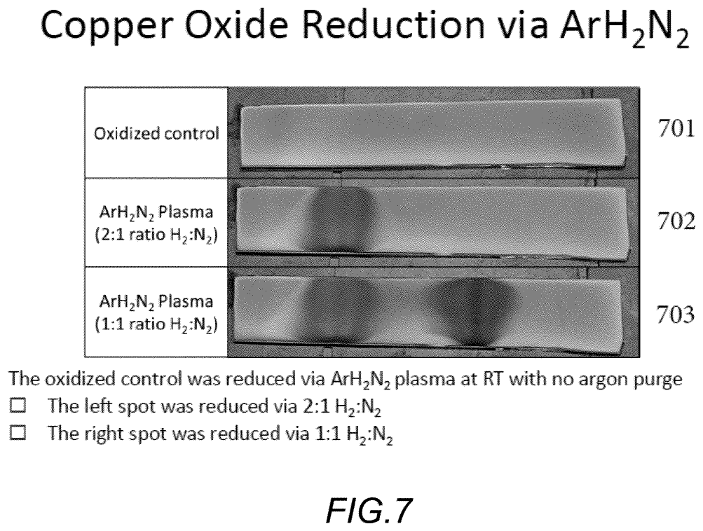

FIG. 7 displays the progression of copper oxide (CuO) removal upon exposure to the atmospheric pressure, mixed gas plasma at room temperature. In this case, the plasma source was held stationary over the sample at 2 mm distance. The 100 mm plasma head was operated at 580 W, 38.0 LPM argon and H₂:N₂ feed ratios of 2:1 and 1:1. The oxide control sample at 701 had an initial yellow-orange color indicating that the CuO film was about 110 nm thick. The picture at 702 was taken after holding the plasma beam with a 2:1 hydrogen to nitrogen ratio over the sample for about one minute. The picture at 703 was taken after holding the plasma beam with a 1:1 hydrogen to nitrogen ratio over the sample at a second spot for about one minute. In both cases, the copper oxide was completely removed directly under the beam. This example demonstrates that the mixed gas plasma will remove copper oxide even at room temperature with no argon purge.

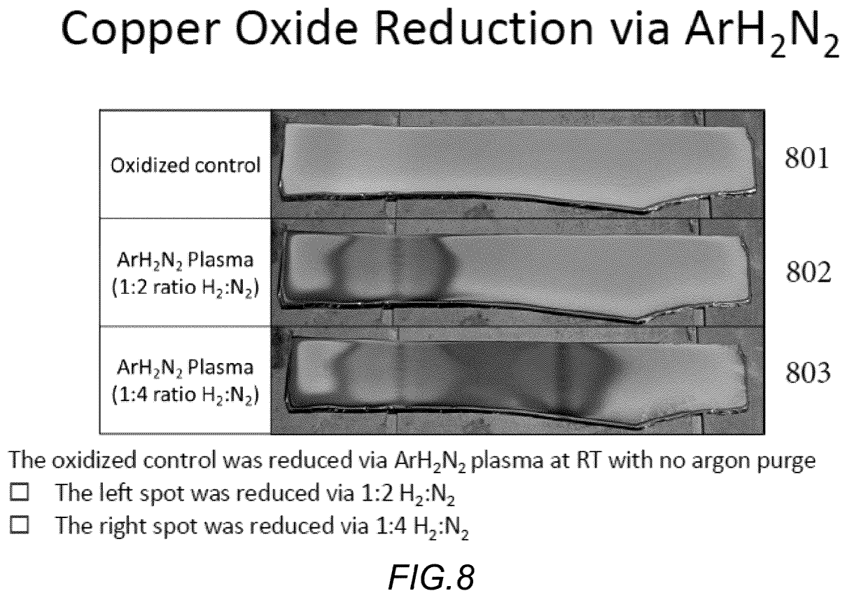

FIG. 8 displays a progression of CuO removal with the atmospheric pressure Ar/H₂/N₂ plasma at 580 W and with H₂:N₂ ratios of 1:2 and 1:4. The picture at 801 is of the oxidized control with a CuO film about 110 nm thick. Placing the beam with the 1 to 2 ratio of hydrogen to nitrogen over the sample at room temperature results in complete removal of the CuO after about one minute, yielding the picture at 802. In addition, placing the beam with the 1 to 4 ratio of hydrogen to nitrogen over the sample at room temperature results in complete removal of the CuO after one minute, yielding the picture at 803.

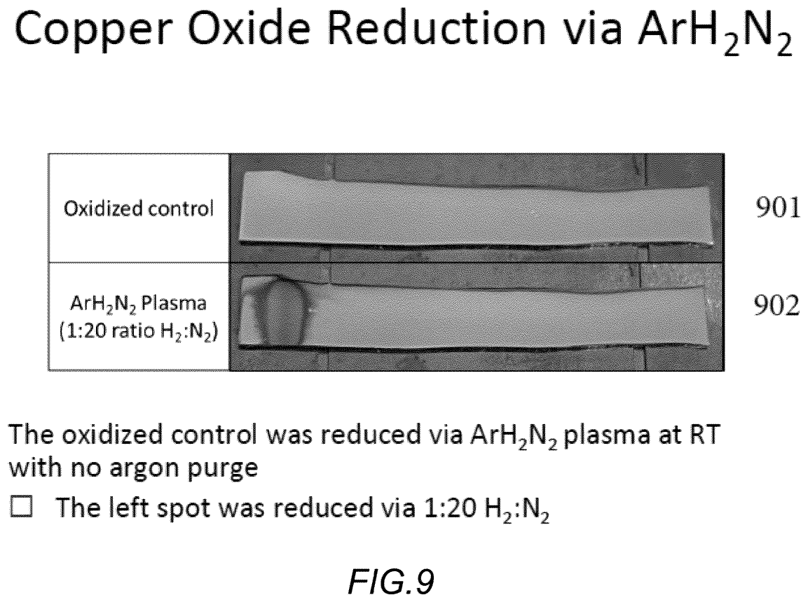

FIG. 9 displays the removal of CuO reduction with the atmospheric pressure Ar/H₂/N₂ plasma at a hydrogen to nitrogen ratio of 1 to 20. A picture of the oxidized control is presented at 901, followed by a picture of the etched CuO underneath the stationary plasma beam at 902. As can be seen in the figure, the oxidized control was reduced via the Ar/H₂/N₂ plasma at room temperature with no argon purge.

In embodiments, the atmospheric pressure, mixed gas plasma fed with argon, nitrogen and hydrogen includes ratios of H₂:O₂ of 3.4:1, 2:1, 1:1, 1:2, 1:4 and 1:20. The results demonstrate that, the oxide layer on copper can be removed with the reactive species exiting the plasma source at room temperature and without the need for an inert gas purge. Separate experiments showed that using an atmospheric pressure argon and oxygen plasma, or an argon and nitrogen plasma, did not remove the oxide layer. Moreover, if the copper was not oxidized than these latter plasmas quickly generated an oxide layer on the copper. Notably, in each embodiment of the present invention, all tested ratios of hydrogen to nitrogen in the mixed gas plasma successfully removed the CuO layer from the copper coupon.

Notably, no drop in plasma activation efficacy is observed when adding H₂ to an Ar/N₂ plasma chemistry, and copper oxide is removed simultaneously with the copper maintained in a reduced state. This state is typically maintained using a chemistry that provides a passivation layer to coat the copper. In this case, however, the combination of chemistry maintains the reduced state without the need for creating a passivation layer. This is in contrast to Ar/N₂ plasma chemistry, which has not been found to reduce the copper oxide.

### Example 5. Improving the Stability of Atmospheric Pressure Nitrogen Plasmas with Addition of Hydrogen

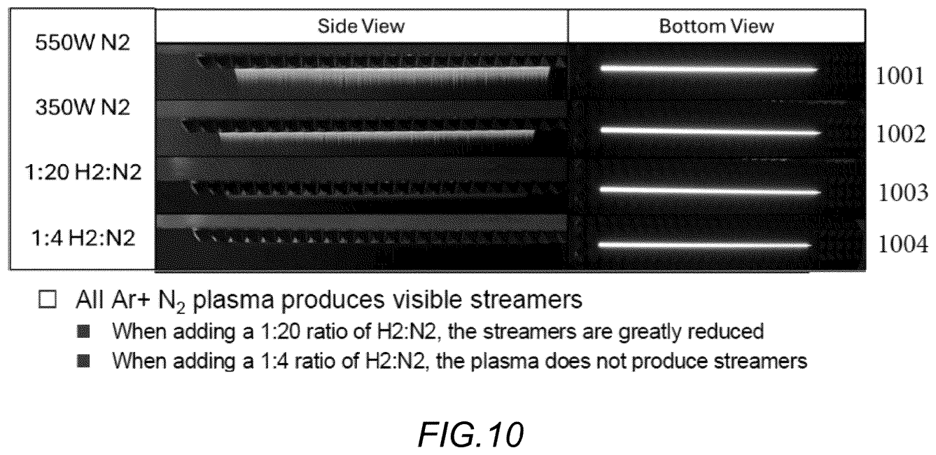

FIG. 10 displays the existence of visible streamers created by an atmospheric pressure, argon and nitrogen plasma, and their elimination with the addition of hydrogen. At 1001 and 1002, pictures are presented of the side and bottom views of a plasma source with a 100 mm wide beam operated at two RF power levels. In 1001, the plasma was operated at 550 W, 40.0 LPM argon and 0.24 LPM nitrogen. In 1002, the plasma was operated at 350 W, 24.0 LPM argon and 0.06 LPM nitrogen. The side views show that at both power levels the nitrogen plasma generates streamers that shoot a few millimeters downstream of the outlet. These streamers indicate that the plasma is somewhat unstable and does not exist in a uniformly glowing state, indicative of a weakly ionized plasma. At 1003, pictures are presented after a small amount of hydrogen is fed to the plasma to yield an H₂:N₂ ratio of 1:20. The plasma power is 580 W. In this case, the streamers are greatly reduced. At 1004, pictures are presented after hydrogen is fed to the argon and nitrogen plasma to yield an H₂:N₂ ratio of 1:4. The plasma power is again 580 W. Here, the streamers are completely eliminated, so that nothing is visible in the side view, but a uniform bright glow is observed in the bottom view looking up into the outlet slit. It is a further embodiment of the invention to add small amounts of hydrogen to atmospheric pressure plasmas fed with other molecules to enhance the stability of the plasma in the weakly ionized state.

Returning to FIG. 2, once the substrate surface is treated as above, in an embodiment, at 206, the substrate can be further processed. For example, in an embodiment, the substrate is further processed by moving it to a hybrid bonder to fuse or bond a treated dielectric layer to another dielectric layer on a second substrate (wafer or die). The dielectric layers can contain micron-sized copper pads, such that hybrid bonding and interconnect formation is accomplished by the fusing together of the two substrates. In an embodiment, the treated substrate is encapsulated or underfilled.

Further embodiments of the invention include the removal of metal oxide layers from other metals as well, including, but not limited to, nickel, palladium, platinum, copper, silver, gold, gallium, indium, tin, or alloys containing these elements. In addition, plasma activation for improved adhesion can be accomplished on many metals, such as copper, silver, nickel, aluminum, titanium and steel. As an example, a copper lead frame could be activated for increased adhesive strength to epoxy molding compounds without needing to remove the copper oxide from the surface. A wide variety of metals can be processed using the principles herein, and would be understood to those skilled in the art.

Thus, summarizing the data, the atmospheric pressure, mixed gas plasma, fed with argon, nitrogen and hydrogen, is just as effective as the atmospheric pressure, argon and oxygen plasma for activating glass (native oxide on silicon), carbon-fiber-reinforced composites, dielectric materials, and polymers. Additionally, the atmospheric pressure, mixed gas plasma does not generate ozone, and maintains metals, such as copper, in their reduced metallic state.

Modifications, additions, or omissions may be made to the systems, apparatuses, and methods described herein without departing from the scope of the disclosure. For example, in the appropriate context, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

This concludes the description, including the various embodiments of the invention. The foregoing description has been presented for the purposes of illustration and description. It is not intended to be exhaustive or to limit the invention to the precise forms disclosed. Many modifications and variations are possible within the scope of the foregoing teachings. Additional variations of the invention may be devised without departing from the inventive concept as set forth in the following claims.

What is claimed is:

1. A method for activating a substrate with a plasma, the method comprising:
directing, from an inlet to a housing configured to define a path for gas flow within the housing, a gas flow comprising a multigas mixture of at least three different gas species combined in a predetermined ratio;
directing the gas flow within the housing between a powered electrode and a grounded electrode;
delivering power from a power supply to ionize the gas flow and produce the plasma comprising reactive neutral species for activating the substrate; and
moving the substrate and the plasma relative to each other at a predetermined scanning speed, such that the plasma activates the substrate.

2. The method of claim 1, wherein the at least three different gas species is argon, nitrogen, and hydrogen.

3. The method of claim 2, where the substrate comprises at least one of an insulator, a semiconductor, a polymer, or a metal.

4. The method of claim 3, where the predetermined scanning speed is between 0.5 and 250 mm/s.

5. The method of claim 4, where the plasma is created from a combination of argon, hydrogen, and nitrogen gas at a predetermined ratio, wherein the argon comprises 97.0% to 99.5% of the gas mixture, and the hydrogen to nitrogen ratio varies from 0.05 to 5.0.

6. The method of claim 5, wherein the plasma is at atmospheric pressure.

7. The method of claim 6, wherein the substrate is held at a temperature between room temperature and 200 degrees C.

8. The method of claim 6, wherein the substrate is not heated.

9. The method of claim 6, wherein the substrate further comprises a dielectric portion and a metallic portion, and wherein the reactive neutral species generated by the plasma prepares the dielectric portion for hybrid bonding, while maintaining the metallic portion in a clean, reduced metallic state.

10. The method of claim 6, further comprising:
moving the substrate to a hybrid bonder; and
hybrid bonding the substrate to at least one of a wafer or die.

11. An apparatus for activating a substrate with a plasma, the apparatus comprising:
a housing configured to support an inlet for a gas flow that comprises a multigas mixture of at least three different gas species combined in a predetermined ratio, the housing configured to define a path for gas flow within the housing;
a powered electrode and a grounded electrode, at least the powered electrode being disposed within the housing, the path for gas flow being disposed between the powered electrode and the grounded electrode;
a power supply coupled to both the powered electrode and the grounded electrode, the power supply configured to deliver power sufficient to produce, from the multigas mixture, a plasma comprising reactive neutral species for activating the substrate; and
a support for the substrate configured to move the substrate and plasma source relative to each other at a predetermined scanning speed, such that the plasma activates the substrate.

12. The apparatus of claim 11, wherein the at least three different gas species is argon, nitrogen, and hydrogen.

13. The apparatus of claim 12, where the substrate comprises at least one of an insulator, a semiconductor, a polymer, or a metal.

14. The apparatus of claim 13, wherein the predetermined scanning speed is between 0.5 and 250 mm/s.

15. The apparatus of claim 14, wherein the plasma is created from a combination of argon, hydrogen, and nitrogen gas at a predetermined ratio, where the argon comprises 97.0% to 99.5% of the gas mixture, and the hydrogen to nitrogen ratio varies from 0.05 to 5.0.

16. The apparatus of claim 15, wherein the plasma is at atmospheric pressure.

17. The apparatus of claim 16, wherein the substrate is held at a temperature between room temperature and 200 degrees C.

18. The apparatus of claim 16, wherein the substrate is not heated.

19. The apparatus of claim 16, where in the substrate comprises a dielectric portion and a metallic portion, and wherein the reactive neutral species generated by the plasma prepares the dielectric portion for hybrid bonding, while maintaining the metallic portion in a clean, reduced metallic state.

20. The apparatus of claim 19, further comprising a hybrid bonder configured to receive the prepared substrate and to hybrid bond the prepared substrate to at least one of a wafer or die.
